(19) United States
(12) Patent Application Publication
(10) Pub. No.: US 2025/0393409 A1
(43) Pub. Date: Dec. 25, 2025

(54) DISPLAY APPARATUS AND DISPLAY PANEL THEREOF

(71) Applicant: HKC CORPORATION LIMITED, SHENZHEN (CN)

(72) Inventors: Zhisheng XIE, SHENZHEN (CN); Yangling TANG, SHENZHEN (CN); Qin LIANG, SHENZHEN (CN); Xiufeng ZHOU, SHENZHEN (CN); Haijiang YUAN, SHENZHEN (CN)

(73) Assignee: HKC CORPORATION LIMITED, SHENZHEN (CN)

(21) Appl. No.: 19/235,641

(22) Filed: Jun. 12, 2025

(30) Foreign Application Priority Data
Jun. 21, 2024 (CN) 202410816835.8

(51) Int. Cl. H10K 59/122

(52) U.S. Cl. CPC H10K 59/122

(57) ABSTRACT

The present application provides a display apparatus and a display panel thereof. The display panel includes a substrate, multiple sub-pixels, a pixel defining layer, and a barrier structure. The multiple sub-pixels are arranged on the substrate. Each sub-pixel includes an anode electrode, a first carrier layer, a light emitting layer, a second carrier layer, and a cathode electrode in sequence and stacked on the substrate. The pixel defining layer is arranged on the substrate to define a position of each of the multiple sub-pixels. The barrier structure is arranged on the pixel defining layer and located between adjacent two sub-pixels. The first carrier layers of the adjacent two sub-pixels are separated by the barrier structure. The cathode electrode and the second carrier layer are both arranged on a side of the barrier structure away from the pixel defining layer, and at least the multiple sub-pixels share the second carrier layer.

### CROSS-REFERENCE TO RELATED APPLICATIONS

The present application claims priority to Chinese Patent Application No. 202410816835.8, entitled “DISPLAY APPARATUS AND DISPLAY PANEL THEREOF”, filed on Jun. 21, 2024, which is herein incorporated by reference in its entirety.

### TECHNICAL FIELD

The present disclosure relates to the technical field of displays, in particular, to a display apparatus and a display panel thereof.

### BACKGROUND

An active matrix organic light emitting diode (AMOLED) display screen is a self-emissive display screen that adopts organic light emitting diode (OLED) technology. It has the advantages of a wide color gamut, high contrast ratio, ultra-thin design, and lower energy consumption, and is thus becoming the preferred choice for next-generation display technology.

With the continuous increase in user requirements for display quality, the resolution of OLED display panels is also increasing. However, while improving the resolution, new problems have arisen, i.e., when a certain target pixel is displayed, one or more surrounding pixels may also light up simultaneously, thereby causing cross-talk between pixels.

### SUMMARY

A first technical solution adopted by the present disclosure is to provide a display panel, including
a substrate;
a plurality of sub-pixels, arranged on the substrate; each of the plurality of the sub-pixels comprising an anode electrode, a first carrier layer, a light emitting layer, a second carrier layer, and a cathode electrode in sequence and stacked on the substrate;
a pixel defining layer, arranged on the substrate to define a position of each of the plurality of the sub-pixels;
a barrier structure, arranged on the pixel defining layer and located between adjacent two sub-pixels; the first carrier layers of the adjacent two sub-pixels being separated by the barrier structure, the cathode electrode and the second carrier layer both being arranged on a side of the barrier structure away from the pixel defining layer, and at least the plurality of sub-pixels sharing the second carrier layer.

A second technical solution adopted by the present disclosure is to provide a display apparatus including a power supply and the display panel in the first technical solution.

### BRIEF DESCRIPTION OF THE DRAWINGS

To more clearly illustrate the technical solutions in the embodiments of the present disclosure, a brief introduction to the drawings used in some embodiments of the present disclosure is provided below. It is evident that the drawings described below are only some of the embodiments of the present disclosure. For those skilled in the art, additional drawings may be derived from these drawings without creative work.

FIG. 1 is a schematic structural view of a display panel in the related art.

FIG. 2 is a schematic structural view of a display panel provided in a first embodiment of the present disclosure.

FIG. 3 is a schematic structural view of a specific embodiment of a barrier structure of the display panel provided in FIG. 2 of the present disclosure.

FIG. 4 is a schematic structural view of a display panel provided in a second embodiment of the present disclosure.

FIG. 5 is a schematic structural view of a specific embodiment of a barrier structure of the display panel provided in FIG. 4 of the present disclosure.

FIG. 6 is a schematic structural view of a display panel provided in a third embodiment of the present disclosure.

FIG. 7 is a schematic structural view of a display panel provided in a fourth embodiment of the present disclosure.

FIG. 8 is a schematic flowchart of a method for manufacturing a display panel provided in some embodiments of the present disclosure.

FIG. 9(a) is a schematic structural view corresponding to an operation in the method for manufacturing the display panel in FIG. 8.

FIG. 9(b) is a schematic structural view corresponding to an operation in the method for manufacturing the display panel in FIG. 8.

FIG. 9(c) is a schematic structural view corresponding to an operation in the method for manufacturing the display panel in FIG. 8.

FIG. 9(d) is a schematic structural view corresponding to an operation in the method for manufacturing the display panel in FIG. 8.

FIG. 9(e) is a schematic structural view corresponding to an operation in the method for manufacturing the display panel in FIG. 8.

FIG. 10 is a schematic structural view of a display apparatus provided in some embodiments of the present disclosure.

### DETAILED DESCRIPTION

The following provides a detailed description of the embodiments of the present disclosure in conjunction with the drawings of the specification.

In the following description, specific details such as particular system structures, interfaces, and technologies are provided for the purpose of illustration rather than limitation, so as to facilitate a thorough understanding of the present disclosure.

The technical solutions in the embodiments of the present invention will be described clearly and completely in the following in conjunction with the accompanying drawings in the embodiments of the present disclosure. It is evident that the embodiments described below are only some of the embodiments of the present disclosure and not all of them. All other embodiments obtained by those skilled in the art without creative effort shall fall within the scope of protection of the present disclosure.

The terms “first,” “second,” and “third” in the present disclosure are merely used for descriptive purposes and should not be construed as indicating or implying relative importance or implicitly indicating the number of the technical features indicated. Thus, features defined with “first,” “second,” and “third” may explicitly or implicitly include at least one such feature. In the description of the present disclosure, the term “multiple” means at least two, for example, two or three, unless specifically defined otherwise. All directional indications (such as up, down, left, right, front, back, etc.) in the embodiments of the present disclosure are only used to describe the relative positional relationship and movement status of components under a specific posture (as shown in the drawings). If the specific posture changes, the directional indications should also be adjusted accordingly. Furthermore, the terms “include,” “have,” and any variations thereof are intended to cover non-exclusive inclusion. For example, a process, a method, a system, a product, or an apparatus that includes a series of steps or components is not limited to those explicitly listed steps or components but may optionally include other steps or components not listed, or may optionally include inherent other steps or components.

References to “an embodiment” in the present disclosure mean that a particular feature, structure, or characteristic described in connection with the embodiment is included in at least one embodiment of the present disclosure. The phrase appearing in various places throughout the specification does not necessarily refer to the same embodiment, and embodiments are not mutually exclusive or alternative unless otherwise indicated. It is explicitly and implicitly understood by those skilled in the art that the embodiments described herein may be combined with other embodiments.

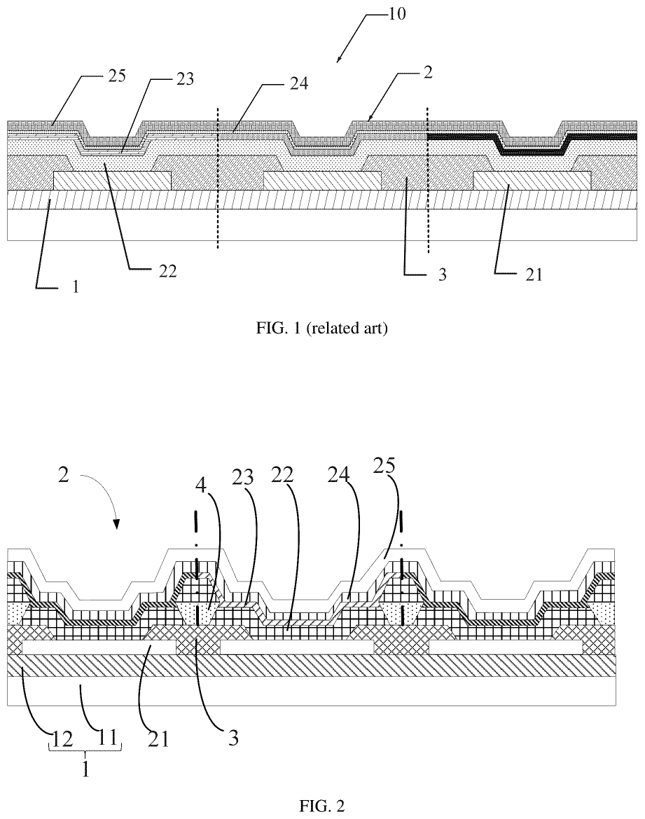

As shown in FIG. 1, FIG. 1 is a schematic structural view of a display panel in the related art.

An AMOLED display has become the mainstream display technology at present. As shown in FIG. 1, an AMOLED display panel 10 includes a substrate 1, an anode electrode 21, a first carrier layer 22, a light emitting layer 23, a second carrier layer 24, a cathode electrode 25, and an encapsulation layer in sequence. When a certain voltage is applied between the cathode electrode 25 and the anode electrode 21, an electron is injected from the cathode electrode 25 into the second carrier layer 24, and a hole is injected from the anode electrode 21 into the first carrier layer 22. Subsequently, the electron migrates through the second carrier layer 24 to the light emitting layer 23, and the hole migrates through the first carrier layer 22 to the light emitting layer 23. The electron and the hole recombine in the light emitting layer 23 to form an exciton. The exciton excites a light emitting molecule, which emits a visible light through radiative relaxation.

The first carrier layer 22 includes a hole injection layer (HIL) and a hole transport layer (HTL). The first carrier layer 22 is provided to enhance an injection speed and a transport speed of the hole, thereby reducing a driving voltage of the OLED device and improving luminous efficiency. As user demands for efficiency continue to increase, in addition to improving the luminous efficiency of the emitting layer (EML) 23 and reducing the driving voltage, a carrier transport rate of the hole injection layer and a carrier transport rate of the hole transport layer are also continuously improved.

However, new problems have also arisen. Currently, adjacent sub-pixels 2 share the first carrier layer 22, the light emitting layer 23, the second carrier layer 24, and the cathode electrode 25. When only one specific sub-pixel 2 needs to be lit, due to the need for hole transport, holes may transfer into an adjacent sub-pixel 2 that does not need to be lit, causing the adjacent sub-pixel 2 to emit light slightly, thereby affecting the display effect.

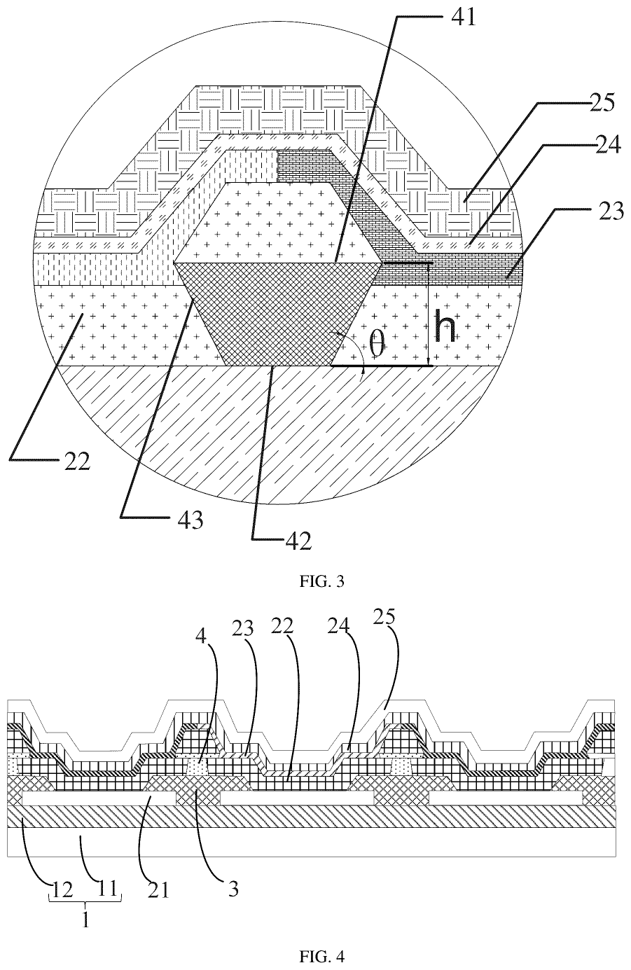

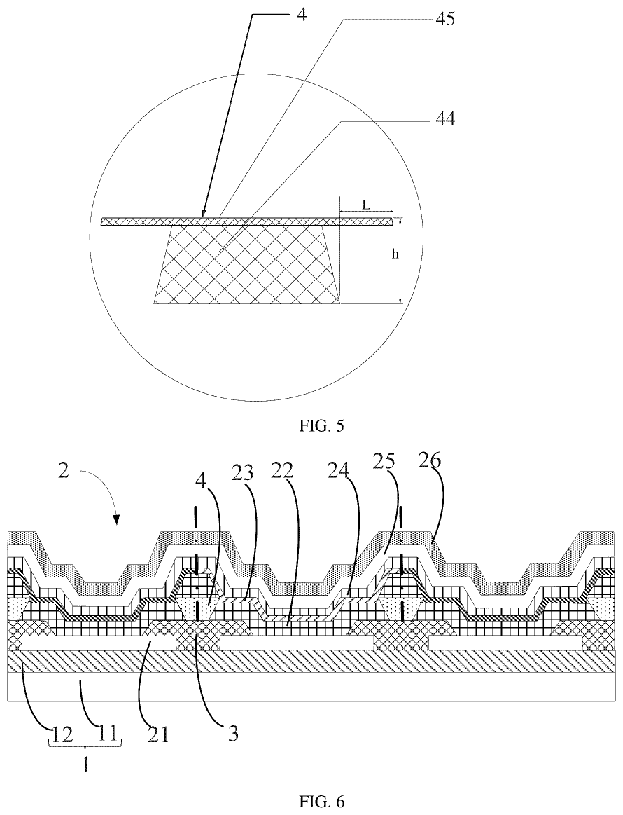

As shown in FIGS. 2 to 5, FIG. 2 is a schematic structural view of a display panel provided in a first embodiment of the present disclosure, FIG. 3 is a schematic structural view of a specific embodiment of a barrier structure of the display panel provided in FIG. 2 of the present disclosure, FIG. 4 is a schematic structural view of a display panel provided in a second embodiment of the present disclosure, FIG. 5 is a schematic structural view of a specific embodiment of a barrier structure of the display panel provided in FIG. 4 of the present disclosure.

To achieve better display efficiency and performance, and to solve the problem of cross-talk while improving the emission and transport efficiency of OLED materials, the present disclosure provides a display panel 10. The display panel 10 includes a substrate 1, multiple sub-pixels 2, a pixel defining layer 3, and a barrier structure 4. The multiple sub-pixels 2 are arranged on the substrate 1. Each sub-pixel 2 includes an anode electrode 21, a first carrier layer 22, a light emitting layer 23, a second carrier layer 24, and a cathode electrode 25 stacked on the substrate 1 in sequence and stacked on the substrate. The pixel defining layer 3 is arranged on the substrate 1 to define a position of each of the multiple sub-pixels 2. The barrier structure 4 is arranged on the pixel defining layer 3 and is located between adjacent two sub-pixels 2. First carrier layers 22 of the adjacent two sub-pixels 2 are separated by the barrier structure 4. The cathode electrode 25 and the second carrier layer 24 are both arranged on a side of the barrier structure 4 away from the pixel defining layer 3, and at least the multiple sub-pixels 2 share the second carrier layer 24.

In the present disclosure, by arranging the barrier structure 4 on the pixel defining layer 3 to block a connection between the first carrier layers 22 of the adjacent two sub-pixels 2, a mutual migration rate of a carrier between the first carrier layers 22 of the adjacent two sub-pixels 2 is reduced, thereby improving the problem of optical cross-talk between sub-pixels 2. By arranging the second carrier layer 24 on a side of the barrier structure 4, multiple sub-pixels 2 may share the second carrier layer 24 and achieve an electrical connection between the cathode electrodes 25 of adjacent sub-pixels 2, thereby further improving the resolution of the display panel 10.

In this embodiment, the substrate 1 includes a base 11 and a driving circuit layer 12. The display panel 10 having the base 11 and the driving circuit layer 12 is an active OLED.

In another embodiment, the substrate 1 includes the base 11. The display panel 10 having the base 11 but not including the driving circuit layer 12 is a passive OLED. The passive OLED includes multiple anode electrodes 21 arranged in parallel and spaced apart, and multiple electrodes 25 arranged in parallel and spaced apart. Each anode electrode 21 of the multiple anode electrodes 21 and a corresponding each cathode electrodes 25 of the multiple cathode electrodes are arranged in a crossed configuration to form an addressing circuit, and are scan-driven through an external PCB circuit board.

The base 11 may be a glass substrate. It may also be a flexible substrate, where the material of the flexible substrate 1 is polyimide (PI). The driving circuit layer 12 may be a thin film transistor (TFT) circuit layer. The TFT circuit layer is configured to drive the light emitting layer 23 of the OLED. In some embodiments, the TFT circuit layer includes multiple driving circuit units arranged in an array, and each driving circuit unit may include a TFT device and a capacitor. Each driving circuit unit corresponds to one anode electrode 21 and one light emitting layer 23. The TFT device may be of a low-temperature poly-silicon (LTPS) type or a metal-oxide semiconductor (MOS) type, for example, a metal-oxide semiconductor type of indium gallium zinc oxide (IGZO).

In this embodiment, the display panel 10 is described in detail using an active OLED as an example.

The pixel defining layer 3 is arranged on the substrate 1, and the pixel defining layer 3 defines a position of each of the multiple sub-pixels 2 on the substrate 1. In some embodiments, the pixel defining layer 3 has a window exposing the anode electrode 21, so that adjacent anode electrodes 21 spaced apart by the pixel defining layer 3 are exposed. In this embodiment, the pixel defining layer 3 has a T-shaped structure. In some embodiments, the pixel defining layer 3 includes a filling portion and a protruding portion that are integrally formed. The filling portion is arranged between the adjacent anode electrodes 21 spaced apart by the pixel defining layer 3, and the protruding portion is arranged on a side of the filling portion away from the substrate 1, and the protruding portion extends to a surface of the anode electrode 21 to cover a portion of an exposed surface of the anode electrode 21. The longitudinal cross-section of the protruding portion may be a rectangular structure or a trapezoidal structure. In this embodiment, a longitudinal cross-section of the protruding portion is a trapezoidal structure, and along the direction from the bottom to the top of the window, the width of the protruding portion gradually decreases.

A material of the pixel defining layer 3 may be one of an organic material, an organic material with an inorganic coating thereon, or an inorganic material. The organic material of the pixel defining layer 3 includes, but is not limited to, polyimide. The inorganic material of the pixel defining layer 3 includes, but is not limited to, silicon dioxide (SiO₂), silicon nitride (Si₃N₄), silicon oxynitride (Si₂N₂O), magnesium fluoride (MgF₂), or combinations thereof.

In one embodiment, sub-pixels 2 corresponding to the active OLED are formed in the multiple windows arranged on the pixel defining layer 3. The sub-pixels 2 in the active OLED include, the anode electrode 21, the first carrier layer 22, the light emitting layer 23, the second carrier layer 24, the cathode electrode 25, and the encapsulation layer in sequence and stacked thereon.

The anode electrode 21 is arranged between the pixel defining layer 3 and the substrate 1. In some embodiments, the anode electrode 21 is arranged on a surface of the TFT circuit layer on a side away from the substrate 1. The anode electrodes 21 are multiple and are arranged spaced apart on a surface of a side of the TFT circuit layer. For example, the multiple anode electrodes 21 are arranged in an array, and each anode electrode 21 corresponds one-to-one to and is electrically connected with a driving circuit unit in the TFT circuit layer. The material of the anode electrode 21 includes, but is not limited to, chromium, titanium, gold, silver, copper, aluminum, ITO, combinations thereof, or other suitable conductive materials.

The barrier structure 4 is arranged on the pixel defining layer 3 and is located between the adjacent two sub-pixels 2. The barrier structure 4 is configured to isolate the first carrier layers 22 of the two adjacent sub-pixels 2, so as to prevent lateral transmission of holes between the first carrier layers 22 of the two adjacent sub-pixels 2, thereby preventing the occurrence of cross-talk and ensuring the display effect of the display panel 10.

In one embodiment, in order to block the lateral transmission of holes between the first carrier layers 22 of the adjacent two sub-pixels 2, an orthographic projection of a surface of the barrier structure 4 close to the pixel defining layer 3 on the pixel defining layer 3 does not exceed an orthographic projection of a surface of the barrier structure 4 away from the pixel defining layer 3 on the pixel defining layer 3. That is, a cross-sectional shape of the barrier structure 4 in a first direction may be an inverted trapezoidal shape, a T-shaped, or the like. The first direction refers to a direction perpendicular to the display panel 10. The barrier structure 4 may be a single-layer structure or a structure of at least two layers. The material of the barrier structure 4 may be one of non-conductive organic materials and non-conductive inorganic materials. The non-conductive inorganic materials include, but are not limited to, inorganic silicon-containing materials. For example, the silicon-containing materials include oxides or nitrides of silicon, or combinations thereof. The non-conductive organic materials include negative-type photosensitive organic materials. For example, the negative-type photosensitive organic materials include, but are not limited to, negative photoresist.

In one embodiment, as shown in FIGS. 2 and 3, the barrier structure 4 is a single-layer structure. The barrier structure 4 includes an upper surface 41 and a lower surface 42 that are parallel to each other, and a side wall 43 connecting the upper surface 41 and the lower surface 42. A center point of the upper surface 41 is coaxially aligned with a center point of the lower surface 42, and an area of the upper surface 41 is greater than an area of the lower surface 42. In this embodiment, the side wall 43 is an inclined surface. An angle between the side wall 43 and a surface of the pixel defining layer 3 must not be too large. If the angle is too large, the separation effect between the first carrier layers 22 of adjacent sub-pixels 2 is poor. The angle must also not be too small. If the angle is too small, the processing of the barrier structure 4 becomes difficult to realize. In some embodiments, in a direction from the lower surface 42 toward the upper surface 41, a width of the barrier structure 4 gradually increases. For example, a longitudinal cross-section of the barrier structure 4 is in an inverted trapezoidal shape.

In this embodiment, an angle θ between the side wall 43 and a surface of the pixel defining layer 3 ranges from 30 degrees to 70 degrees. In one specific embodiment, the angle between the side wall 43 and the surface of the pixel defining layer 3 ranges from 45 degrees to 60 degrees. For example, the angle between the side wall 43 and the surface of the pixel defining layer 3 may be 35 degrees, 40 degrees, 45 degrees, 50 degrees, 55 degrees, 60 degrees, 65 degrees, or 70 degrees, and may be specifically set according to actual conditions.

In other embodiments, the side wall 43 may also be a curved surface. For example, the curved surface may be a convex curved surface or a concave curved surface.

In one embodiment, in order to effectively improve the optical cross-talk between adjacent sub-pixels 2, the barrier structure 4 may be configured as a two-layer structure. As shown in FIGS. 4 and 5, the barrier structure 4 specifically includes a first barrier portion 44 and a second barrier portion 45 that are stacked. The first barrier portion 44 is arranged between the second barrier portion 45 and the pixel defining layer 3. A width of an orthographic projection of the second barrier portion 45 on the pixel defining layer 3 is greater than a width of an orthographic projection of the first barrier portion 44 on the pixel defining layer 3. That is, the orthographic projection of the second barrier portion 45 on the pixel defining layer 3 completely covers the orthographic projection of the first barrier portion 44 on the pixel defining layer 3, and any side edge of the orthographic projection of the second barrier portion 45 on the pixel defining layer 3 does not overlap with a side edge of the orthographic projection of the first barrier portion 44 on the pixel defining layer 3.

In some embodiments, the cross-sectional shape of the first barrier portion 44 in the first direction may be a rectangle, trapezoid, or inverted trapezoid. A cross-sectional shape of the second barrier portion 45 in the first direction may be a rectangle, a regular trapezoid, or an inverted trapezoid. An orthographic projection of a surface of the first barrier portion 44 close to the second barrier portion 45 is completely within an orthographic projection of a surface of the second barrier portion 45 close to the first barrier portion 44. In this embodiment, a central axis of the first barrier portion 44 in the first direction coincides with a central axis of the second barrier portion 45 in the first direction. Materials of the first barrier portion 44 and the second barrier portion 45 may be the same or may be different. The materials of the first barrier portion 44 and the second barrier portion 45 may be at least one of non-conductive inorganic materials and non-conductive organic materials.

In the following embodiment, the barrier structure 4 including a first barrier portion 44 having a trapezoidal cross-section in the first direction and a second barrier portion 45 having a rectangular cross-section in the first direction is described as an example.

To improve the blocking effect, a distance between an orthographic projection of a side edge of the second barrier portion 45 on the pixel defining layer 3 and an orthographic projection of a corresponding side edge of the first barrier portion 44 on the pixel defining layer 3 ranges from 0.005 μm to 0.15 μm. In one embodiment, the distance between an orthographic projection of a side edge of the second barrier portion 45 on the pixel defining layer 3 and an orthographic projection of a corresponding side edge of the first barrier portion 44 on the pixel defining layer 3 ranges from 0.01 μm to 0.1 μm. In another embodiment, the distance between an orthographic projection of a side edge of the second barrier portion 45 on the pixel defining layer 3 and an orthographic projection of a corresponding side edge of the first barrier portion 44 on the pixel defining layer 3 ranges from 0.02 μm to 0.05 μm. In some embodiments, the distance between an orthographic projection of a side edge of the second barrier portion 45 on the pixel defining layer 3 and an orthographic projection of a corresponding side edge of the first barrier portion 44 on the pixel defining layer 3 may be 0.03 μm, 0.04 μm, 0.07 μm, 0.08 μm, 0.09 μm, etc., and may be specifically set according to actual conditions.

In one embodiment, in order to improve the blocking effect and facilitate the formation of a shared second carrier layer 24 on the barrier structure 4, a thickness ratio between the first barrier portion 44 and the second barrier portion 45 ranges from 5:1 to 3:1. In one embodiment, the thickness ratio between the first barrier portion 44 and the second barrier portion 45 ranges from 4:1 to 3:1. In one embodiment, the thickness ratio between the first barrier portion 44 and the second barrier portion 45 may be 5:1, 4:1, or 3:1, and may be specifically set according to actual conditions.

In other embodiments, the barrier structure 4 may also be configured as a multilayer structure.

The first carrier layer 22 includes a hole injection layer and a hole transport layer stacked in sequence. The hole injection layer is arranged on a surface of the anode electrode 21 and a surface of the barrier structure 4 on a side away from the substrate 1. That is, the hole injection layer covers an exposed surface of the anode electrode 21 and an exposed surface of the barrier structure 4 on a side away from the substrate 1. The hole injection layer may reduce an injection barrier of holes, improve the injection efficiency of holes, and reduce a voltage of the display panel 10. The hole transport layer is arranged on a surface of the hole injection layer away from a side of the anode electrode 21, that is, the hole transport layer covers a surface of the hole injection layer that is away from the anode electrode 21 and an exposed surface of the barrier structure 4 that is away from the substrate 1. The hole transport layer is configured to transport hole carriers and transfer the holes in the hole injection layer to the light emitting layer 23.

The hole injection layer may facilitate the injection of holes from the anode electrode 21 to the hole transport layer. The hole injection layer may be formed using hole injection materials such as copper phthalocyanine (CuPc), poly 3,4-ethylenedioxythiophene (PEDOT), polyaniline (PANI), or mixtures thereof. The hole injection layer may be formed by processes such as vacuum evaporation, thermal evaporation, slit coating, spin coating, printing, etc. A portion of the hole injection layer covering the barrier structure 4 is separated from a portion covering the anode electrode 21.

The hole transport layer may be formed using hole transport materials such as 4,4′-bis [N-(1-naphthyl)-N-phenylamino]biphenyl (NPB), N,N′-diphenyl-N,N′-bis(3-methylphenyl)-1,1′-biphenyl-4,4′-diamine (TPD), N,N′-di-1-naphthyl-N,N′-biphenyl-1,1′-diphenyl-4,4′-diamine (NPD), N-phenylcarbazole, polyvinylcarbazole, or mixtures thereof. The hole transport layer may be formed by processes such as vacuum evaporation, thermal evaporation, slit coating, spin coating, printing, etc. The portion of the hole transport layer covering the barrier structure 4 is separated from the portion covering the anode electrode 21. As a result, the portion of the first carrier layer 22 covering the barrier structure 4 is disconnected from the portion covering the anode electrode 21.

In one embodiment, the first carrier layer 22 only covers the anode electrode 21, and the surface of the barrier structure 4 on the side away from the substrate 1 is not covered by the first carrier layer 22, thereby avoiding lateral transmission of holes between the first carrier layers 22 of the adjacent two sub-pixels 2.

The light emitting layer 23 may include a red light emitting layer 23, a green light emitting layer 23, and a blue light emitting layer 23. The light emitting layer 23 may be formed using suitable light emitting materials that generate red, green, or blue light according to the emission mechanism of the light emitting layer 23, such as fluorescence or phosphorescence. The light emitting layer 23 may be obtained by a printing process such as inkjet printing, spin coating, or nozzle printing, or by a transfer process using the substrate 1 through heat or laser.

In this embodiment, in order to improve luminous efficiency, multiple sub-pixels 2 share the same second carrier layer 24. That is, the second carrier layer 24 in this embodiment may be a single layer, and the second carrier layer 24 covers the light emitting layers 23 of multiple sub-pixels 2. In one embodiment, at least the light emitting layers 23 of adjacent two sub-pixels 2 share the same second carrier layer 24.

The second carrier layer 24 includes an electron transport layer and an electron injection layer stacked in sequence.

The electron transport layer is arranged on the surface of the light emitting layer 23 on a side away from the first carrier layer 22. The electron transport layer may be formed using, for example, tris(8-hydroxyquinolinato)aluminum (Alq3), 2-(4-biphenyl)-5-(4-tert-butylphenyl)-1,3,4-oxadiazole (PBD), bis(2-methyl-8-hydroxyquinoline)-4-phenylphenoxide-aluminum (BAlq), 2,9-dimethyl-4,7-diphenyl-1,10-phenanthroline (BCP), and the like. These compounds may be used alone or in combination.

The electron injection layer is arranged on a surface of the electron transport layer on a side away from the light emitting layer 23. The electron injection layer may be formed using alkali metals, alkaline earth metals, fluorides of these metals, oxides of these metals, etc. These materials may be used alone or in combination.

The cathode electrode 25 may be formed using a transparent conductive material or a metal, depending on its type, such as a transparent electrode or a reflective electrode. The transparent conductive material may include ITO, ZTO, IZO, ZnOx, SnOx, GIZO, AZO, etc. The metal may include, for example, Ag, Al, Pt, Au, Cr, W, Mo, Ti, Pd, or alloys thereof. The cathode electrode 25 may be obtained by sputtering, chemical vapor deposition (CVD), atomic layer deposition (ALD), vacuum deposition, printing, or other processes.

In this embodiment, the second carrier layer 24 covering the layers of the multiple sub-pixels 2 is a continuous layer, and the barrier structure 4 does not block the second carrier layer 24. The cathode electrode 25 covering the second carrier layer 24 is also a continuous layer, that is, the cathode electrodes 25 of the multiple sub-pixels 2 form an integrated structure, and the barrier structure 4 does not block the cathode electrode 25.

In one embodiment, in order to better block the lateral transmission of holes between the first carrier layers 22 of adjacent two sub-pixels 2, a surface of the first carrier layer 22 away from the substrate 1 does not exceed a surface of the barrier structure 4 away from the substrate 1.

Since a total thickness of the first carrier layer 22 is approximately 0.14 μm, a thickness of the barrier structure 4 only needs to be slightly greater than the total thickness of the first carrier layer 22 covering the anode electrode 21. Since a thickness of the light emitting layer 23 is approximately 0.04 μm, a thickness of the second carrier layer 24 is approximately 0.03 μm, and a thickness of the cathode electrode 25 is approximately 0.06 μm, if the thickness of the barrier structure 4 is too large, then a combined thickness of the light emitting layer 23 and the second carrier layer 24 on top of the first carrier layer 22 may not be sufficient to completely cover the barrier structure 4, which may result in the cathode electrode 25 being blocked.

In one embodiment, a thickness h of the barrier structure 4 ranges from 0.1 μm to 0.3 μm. In one embodiment, the thickness of the barrier structure 4 ranges from 0.15 μm to 0.25 μm. In one embodiment, the thickness of the barrier structure 4 ranges from 0.12 μm to 0.18 μm. In one embodiment, the thickness of the barrier structure 4 may be 0.13 μm, 0.14 μm, 0.15 μm, 0.16 μm, 0.17 μm, etc., and may be specifically set according to actual conditions.

In one embodiment, a difference in thickness between the barrier structure 4 and the first carrier layer 22 ranges from 0.25 μm to 0.75 μm. In one embodiment, the difference in thickness between the barrier structure 4 and the first carrier layer 22 ranges from 0.25 μm to 0.75 μm. In one embodiment, the difference in thickness between the barrier structure 4 and the first carrier layer 22 may be 0.35 μm, 0.4 μm, 0.45 μm, 0.5 μm, 0.55 μm, 0.6 μm, 0.65 μm, 0.7 μm, etc., and may be specifically set according to actual conditions.

As shown in FIG. 6, FIG. 6 is a schematic structural view of a display panel provided in a third embodiment of the present disclosure.

In one embodiment, in order to facilitate conduction between the cathode electrodes 25 of adjacent sub-pixels 2 and reduce the risk that the cathode electrodes 25 may also be blocked by the barrier structure 4 when solving the cross-talk issue, a cathode auxiliary layer 26 is arranged on a side of the cathode electrode 25 away from the barrier structure 4. The cathode electrodes 25 of adjacent two sub-pixels 2 are electrically connected through the cathode auxiliary layer 26. A material of the cathode auxiliary layer 26 may be the same as or different from the material of the cathode electrode 25.

In one embodiment, a thickness of the cathode auxiliary layer 26 ranges from 0.025 μm to 0.15 μm. In one embodiment, the thickness of the cathode auxiliary layer 26 ranges from 0.05 μm to 0.1 μm. In one embodiment, a thickness of the cathode auxiliary layer 26 may be 0.06 μm, 0.07 μm, 0.08 μm, 0.09 μm, etc., and may be specifically set according to actual conditions.

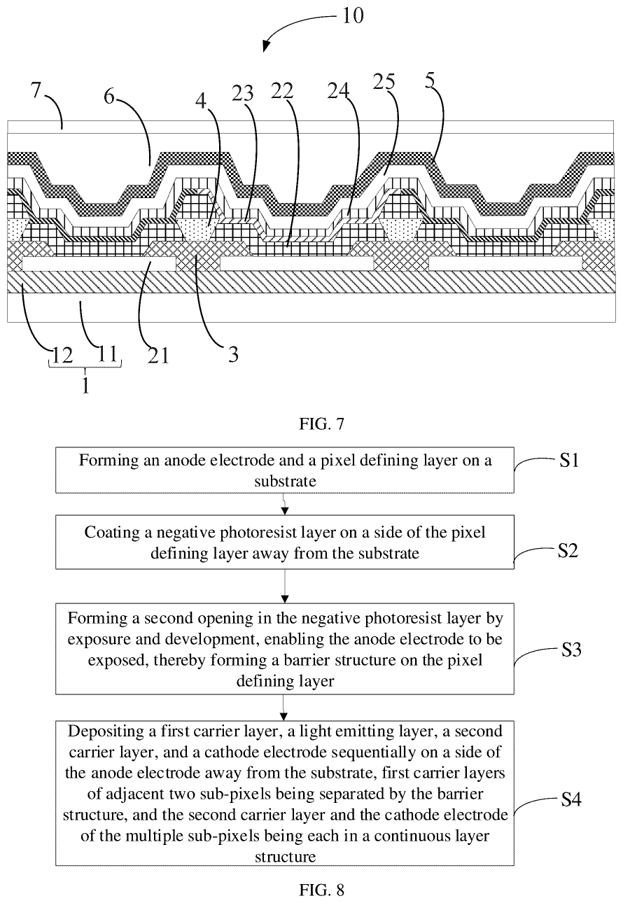

As shown in FIG. 7, FIG. 7 is a schematic structural view of a display panel provided in a fourth embodiment of the present disclosure.

In one embodiment, the display panel 10 further includes an encapsulation layer 5. The encapsulation layer 5 is arranged on the surface of the cathode electrode 25 on a side away from the light emitting layer 23, enabling the encapsulation layer 5 to cover an exposed surface of the sub-pixel 2. The encapsulation layer 5 includes a non-conductive inorganic material. The non-conductive inorganic material includes a silicon-containing material. The silicon-containing material may include a material containing Si₃N₄.

In this embodiment, the encapsulation layer 5 is formed by a vaporization process.

In one embodiment, the display panel 10 further includes a filling layer 6 and a cover plate 7. The filling layer 6 fills a recessed region of each sub-pixel 2, enabling a surface of each sub-pixel 2 away from the substrate 1 to form a planar surface, facilitating a sealing of the surface of each of the sub-pixels 2 by the cover plate 7. A material of the filling layer 6 is transparent. The cover plate 7 may be a glass cover plate or may be a plastic film such as polyethylene terephthalate (PET).

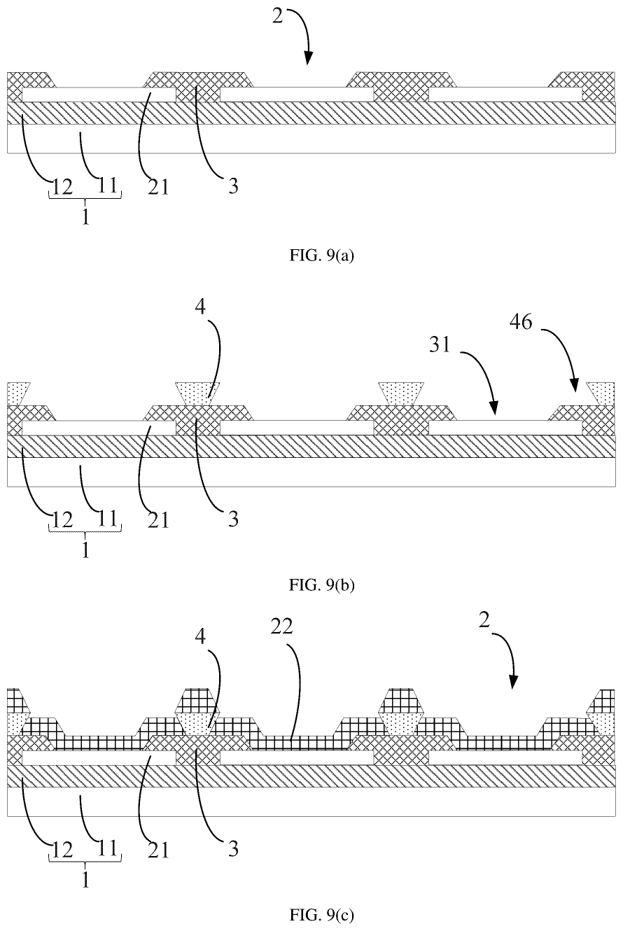

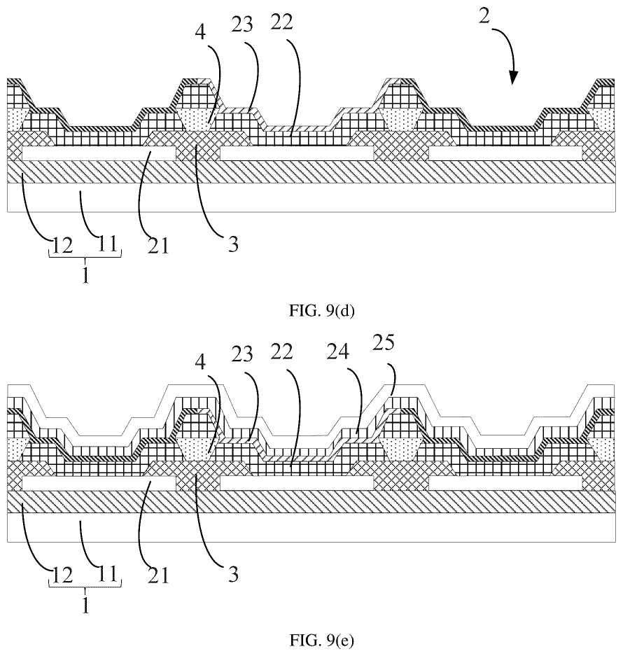

As shown in FIG. 8 and FIGS. 9(a) to 9(e), FIG. 8 is a schematic flowchart of a method for manufacturing a display panel provided in some embodiments of the present disclosure, FIGS. 9(a) to 9(e) are schematic structural views corresponding to each operation in the method for manufacturing the display panel in FIG. 8.

A method for manufacturing a display panel 10 is provided in this embodiment. The method for manufacturing the display panel 10 includes the following operations.

At block S1, an anode electrode and a pixel defining layer is formed on a substrate.

In some embodiments, anode electrodes 21 are spaced apart and are formed on the substrate 1, and the pixel defining layer 3 is formed on a side of the anode electrodes 21 away from the substrate 1. A mask plate is placed over the surface of the pixel defining layer 3 that is away from the substrate 1, and first openings 31 that are spaced apart are defined on the pixel defining layer by dry etching, enabling the anode electrodes 21 to be exposed through the first openings 31. The mask plate is removed. The pixel defining layer 3 defines the anode electrodes 21 to form sub-pixels 2, as shown in FIG. 9(a).

At block S2, a negative photoresist layer on a side of the pixel defining layer away from the substrate is coated.

In some embodiments, the negative photoresist layer is arranged on the side of the pixel defining layer 3 away from the substrate 1, and the negative photoresist layer fills the first openings 31. A surface of the negative photoresist layer on the side away from the substrate 1 is planar.

At block S3, a second opening is formed in the negative photoresist layer by exposure and development, enabling the anode electrode to be exposed, thereby forming a barrier structure on the pixel defining layer.

In some embodiments, during the exposure process, an irradiated portion of the negative photoresist layer undergoes polymerization and cross-linking curing, while an unexposed portion does not undergo polymerization. A surface of the negative photoresist layer is more susceptible to polymerization and cross-linking, and a light intensity gradually decreases from the surface of the negative photoresist layer in a direction away from the surface. Thus, a degree of polymerization and cross-linking of the negative photosensitive material gradually decreases in a direction away from the surface. During the development process, an unpolymerized and uncross-linked negative photoresist is removed.

A mask plate covers a surface of the negative photoresist layer on a side away from the substrate 1. By using a light, exposed regions of the negative photoresist layer undergo polymerization and cross-linking, while the unexposed regions remain unpolymerized. After a preset exposure time, an unpolymerized and uncross-linked portion of the negative photoresist is removed using a developer to form a second opening 46 in the negative photoresist layer. The polymerized and crosslinked portion of the negative photoresist layer serves as an inverted trapezoidal barrier structure 4. An angle is formed between a side wall 43 of the barrier structure 4 and the pixel defining layer 3, as shown in FIG. 9(b).

At block S4, a first carrier layer, a light emitting layer, a second carrier layer, and a cathode electrode are sequentially deposited on a side of the anode electrode away from the substrate. First carrier layers of adjacent two sub-pixels are separated by the barrier structure. The second carrier layer and the cathode electrode of the multiple sub-pixels are each in a continuous layer structure.

In some embodiments, a hole injection layer and a hole transport layer are sequentially arranged on a side of the anode electrode 21 away from the substrate 1. The hole injection layer and the hole transport layer together form the first carrier layer 22. A surface of the first carrier layer 22 on a side away from the substrate 1 is not higher than a surface of the barrier structure 4 on a side away from the substrate 1. At the same time, a portion of the first carrier layer 22 is also deposited on a surface of the barrier structure 4 away from the substrate 1. The first carrier layer 22 deposited on the barrier structure 4 is disconnected from the first carrier layer 22 arranged inside the second opening 46, as shown in FIG. 9(c).

Light emitting layers 23 corresponding to different sub-pixels 2 are deposited on a surface of the first carrier layer 22 on a side away from the substrate 1. The light emitting layer 23 may include a red light emitting layer, a green light emitting layer, and a blue light emitting layer. In some embodiments, a red light emitting layer 23 may be deposited on the first carrier layer 22 of a first sub-pixel 2, a green light emitting layer 23 may be deposited on the first carrier layer 22 of a second sub-pixel 2, and a blue light emitting layer 23 may be deposited on the first carrier layer 22 of a third sub-pixel 2, as shown in FIG. 9(d).

An electron transport layer and an electron injection layer are sequentially deposited on a surface of the light emitting layer 23 on a side away from the first carrier layer 22. The electron transport layer and the electron injection layer together form the second carrier layer 24. The second carrier layer 24 covering the layers of the multiple sub-pixels 2 is a continuous layer, and the barrier structure 4 does not block the second carrier layer 24, as shown in FIG. 9(e).

A conductive material is deposited on the surface of the second carrier layer 24 on the side away from the substrate 1 and the light emitting layer 23, thereby forming a transparent cathode electrode 25. The cathode electrode 25 covering the second carrier layer 24 is also a continuous layer, that is, the cathode electrodes 25 of the multiple sub-pixels 2 form an integrated structure, and the barrier structure 4 does not block the cathode electrode 25, as shown in FIG. 9(e).

In one embodiment, a cathode auxiliary layer 26 is formed by deposition on a side of the cathode electrode 25 away from the second carrier layer 24, so that the cathode electrodes 25 of adjacent two sub-pixels 2 are electrically connected to each other, as shown in FIG. 6.

An encapsulation layer 5 is formed by a vaporization process on a surface of the cathode electrode 25 on a side away from the second carrier layer 24. The encapsulation layer 5 is arranged on a surface of the cathode electrode 25 on a side away from the light emitting layer 23, so that the encapsulation layer 5 covers an exposed surface of the sub-pixels 2.

A filling layer 6 and a cover plate 7 are arranged on a side of the encapsulation layer 5 away from the substrate 1. The filling layer 6 fills a recessed region of each sub-pixel 2 so that a surface of the sub-pixels 2 away from the substrate 1 forms a planar surface, facilitating the sealing of the surface of the sub-pixels 2 by the cover plate 7. The material of the filling layer 6 is a transparent material. The cover plate 7 may be a glass cover plate or a plastic film such as PET, as shown in FIG. 7.

In the method for manufacturing the display panel 10 provided in this embodiment, a barrier structure 4 is arranged on the pixel defining layer 3 to block the connection between the first carrier layers 22 of adjacent two sub-pixels 2, thereby reducing the mutual migration rate of carriers between the first carrier layers 22 of adjacent two sub-pixels 2, and thus improving the problem of optical cross-talk between sub-pixels 2. By disposing the second carrier layer 24 on a side of the barrier structure 4, it is possible to allow multiple sub-pixels 2 to share the second carrier layer 24 and to achieve an electrical connection between the cathode electrodes 25 of adjacent sub-pixels 2, thereby further improving the resolution of the display panel 10.

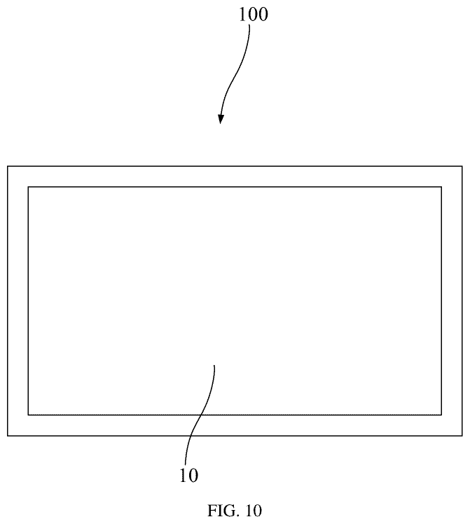

As shown in FIG. 10, FIG. 10 is a schematic structural view of a display apparatus provided in some embodiments of the present disclosure.

In this embodiment, a display apparatus 100 is provided. The display apparatus 100 may be used in fields such as tablets, mobile phones, automotive displays, lighting, etc.

The display apparatus 100 includes a display panel 10. The specific structure and functions of the display panel 10 are the same as or similar to the specific structure and functions of the display panel 10 described in the above embodiments, and may achieve the same technical effects. Details may refer to the above description, which will not be repeated here.

The display panel 10 in the display apparatus 100 adopts the display panel 10 in the above embodiments. The barrier structure 4 is arranged on the pixel defining layer 3 to block the connection between the first carrier layers 22 of adjacent two sub-pixels 2, thereby reducing the mutual migration rate of carriers between the first carrier layers 22 of two adjacent sub-pixels 2 and improving the problem of optical cross-talk between sub-pixels 2. By arranging the second carrier layer 24 on a side of the barrier structure 4, it is possible to allow multiple sub-pixels 2 to share the second carrier layer 24 and to achieve an electrical connection between the cathode electrodes 25 of adjacent sub-pixels 2, thereby further improving the resolution of the display panel 10.

The above are merely embodiments of the present disclosure and are not intended to limit the scope of patent protection of the present disclosure. Any equivalent structural or procedural transformations made based on the content of the specification and drawings of the present disclosure, or any direct or indirect application in other related technical fields, shall likewise fall within the scope of protection of the present disclosure.

1. A display panel, comprising:
a substrate;
a plurality of sub-pixels, arranged on the substrate; each of the plurality of the sub-pixels comprising an anode electrode, a first carrier layer, a light emitting layer, a second carrier layer, and a cathode electrode in sequence and stacked on the substrate;
a pixel defining layer, arranged on the substrate to define a position of each of the plurality of the sub-pixels;
a barrier structure, arranged on the pixel defining layer and located between adjacent two sub-pixels; the first carrier layers of the adjacent two sub-pixels being separated by the barrier structure, the cathode electrode and the second carrier layer both being arranged on a side of the barrier structure away from the pixel defining layer, and at least the plurality of sub-pixels sharing the second carrier layer.

2. The display panel according to claim 1, wherein a surface of the first carrier layer away from the substrate does not exceed a surface of the barrier structure away from the substrate.

3. The display panel according to claim 2, wherein a difference in thickness between the barrier structure and the first carrier layer is not less than 0.25 microns and not more than 0.75 microns.

4. The display panel according to claim 3, wherein a thickness of the barrier structure is not less than 0.1 microns and not more than 0.3 microns.

5. The display panel according to claim 1, wherein an orthographic projection of a surface of the barrier structure close to the pixel defining layer on the pixel defining layer does not exceed an orthographic projection of a surface of the barrier structure away from the pixel defining layer on the pixel defining layer.

6. The display panel according to claim 5, wherein the barrier structure comprises a first barrier portion and a second barrier portion stacked together, the first barrier portion is arranged between the second barrier portion and the pixel defining layer, and a width of an orthographic projection of the second barrier portion on the pixel defining layer is greater than a width of an orthographic projection of the first barrier portion on the pixel defining layer.

7. The display panel according to claim 6, wherein a thickness ratio between the first barrier portion and the second barrier portion ranges from 5:1 to 3:1; and/or a distance between an orthographic projection of a side edge of the second barrier portion on the pixel defining layer and an orthographic projection of a corresponding side edge of the first barrier portion on the pixel defining layer is not less than 0.005 microns and not more than 0.15 microns.

8. The display panel according to claim 5, wherein the barrier structure comprises an upper surface and a lower surface that are parallel to each other, and a side wall connecting the upper surface and the lower surface; and an angle between the side wall and the pixel defining layer ranges from 30 degrees to 70 degrees.

9. The display panel according to claim 1, wherein a cathode auxiliary layer is arranged on a side of the cathode electrode away from the barrier structure, the cathode electrodes of the adjacent two sub-pixels are electrically connected through the cathode auxiliary layer, and a thickness of the cathode auxiliary layer is not less than 0.025 microns and not more than 0.15 microns.

10. The display panel according to claim 1, wherein the pixel defining layer has a window exposing the anode electrode, the pixel defining layer exposes adjacent anode electrodes in a spaced manner.

11. A display apparatus, comprising a display panel and a power supply, the display panel comprising:
a substrate;
a plurality of sub-pixels, arranged on the substrate; each of the plurality of the sub-pixels comprising an anode electrode, a first carrier layer, a light emitting layer, a second carrier layer, and a cathode electrode in sequence and stacked on the substrate;
a pixel defining layer, arranged on the substrate to define a position of each of the plurality of the sub-pixels;
a barrier structure, arranged on the pixel defining layer and located between adjacent two sub-pixels; the first carrier layers of the adjacent two sub-pixels being separated by the barrier structure, the cathode electrode and the second carrier layer both being arranged on a side of the barrier structure away from the pixel defining layer, and at least the plurality of sub-pixels sharing the second carrier layer.

12. The display apparatus according to claim 11, wherein a surface of the first carrier layer away from the substrate does not exceed a surface of the barrier structure away from the substrate.

13. The display apparatus according to claim 12, wherein a difference in thickness between the barrier structure and the first carrier layer is not less than 0.25 microns and not more than 0.75 microns.

14. The display apparatus according to claim 13, wherein a thickness of the barrier structure is not less than 0.1 microns and not more than 0.3 microns.

15. The display apparatus according to claim 11, wherein an orthographic projection of a surface of the barrier structure close to the pixel defining layer on the pixel defining layer does not exceed an orthographic projection of a surface of the barrier structure away from the pixel defining layer on the pixel defining layer.

16. The display apparatus according to claim 15, wherein the barrier structure comprises a first barrier portion and a second barrier portion stacked together, the first barrier portion is arranged between the second barrier portion and the pixel defining layer, and a width of an orthographic projection of the second barrier portion on the pixel defining layer is greater than a width of an orthographic projection of the first barrier portion on the pixel defining layer.

17. The display apparatus according to claim 16, wherein a thickness ratio between the first barrier portion and the second barrier portion ranges from 5:1 to 3:1; and/or a distance between an orthographic projection of a side edge of the second barrier portion on the pixel defining layer and an orthographic projection of a corresponding side edge of the first barrier portion on the pixel defining layer is not less than 0.005 microns and not more than 0.15 microns.

18. The display apparatus according to claim 15, wherein the barrier structure comprises an upper surface and a lower surface that are parallel to each other, and a side wall connecting the upper surface and the lower surface; and an angle between the side wall and the pixel defining layer ranges from 30 degrees to 70 degrees.

19. The display apparatus according to claim 11, wherein a cathode auxiliary layer is arranged on a side of the cathode electrode away from the barrier structure, the cathode electrodes of the adjacent two sub-pixels are electrically connected through the cathode auxiliary layer, and a thickness of the cathode auxiliary layer is not less than 0.025 microns and not more than 0.15 microns.

20. The display apparatus according to claim 11, wherein the pixel defining layer has a window exposing the anode electrode, the pixel defining layer exposes adjacent anode electrodes in a spaced manner.
